(19) United States
(12) Patent Application Publication
(10) Pub. No.: US 2015/0171303 A1
(43) Pub. Date: Jun. 18, 2015

(54) THERMOELECTRIC GENERATOR PIPE AND METHOD FOR PRODUCING THE GENERATOR PIPE

(71) Applicant: SIEMENS AKTIENGESELLSCHAFT, Munich (DE)

(72) Inventors: Steffen Lang, Hallerndorf (DE); Bastian Plochmann, Neustadt/Aisch (DE)

(73) Assignee: SIEMENS AKTIENGESELLSCHAFT, Munich (DE)

(21) Appl. No.: 14/401,688

(22) PCT Filed: Mar. 26, 2013
(86) PCT No.: PCT/EP2013/056380

§ 371 Date: Nov. 17, 2014

(30) Foreign Application Priority Data
May 16, 2012 (DE) 10 2012 208 225.5

(51) Int. Cl. H01L 35/32; H01L 21/64

(52) U.S. Cl. CPC H01L 35/32; H01L 21/64

(57) ABSTRACT

A thermoelectric generator pipe for producing electrical energy, surrounds a heat source or a heat sink. The generator pipe is formed by a helix structure having an inner and outer conductor strips that are electrically conductive. The conductor strips have substantially the same width and are wound with the same pitch. Between the inner and outer conductor strips, first and second intermediate axial spaces are formed, which are each arranged between one edge of the inner conductor strip and the edge of the immediately adjacent outer conductor strip. The intermediate spaces are formed as a double helix. First and second layers are arranged respectively in the first and second intermediate spaces. The first and second layers are formed respectively from n-doped and p-doped, thermoelectric and percolating particles. The generator pipe is slit subdivided in the axial direction to produce sections that form thermoelectric elements connected in series.

### CROSS REFERENCE TO RELATED APPLICATIONS

This application is based on and hereby claims priority to International Application No. PCT/EP2013/056380 filed on Mar. 26, 2013 and German Application No. 10 2012 208 225.5 filed on May 16, 2012, the contents of which are hereby incorporated by reference.

### BACKGROUND

The invention relates to a thermoelectric generator pipe for generating electrical energy and to a method for producing the generator pipe.

For the generation of electrical energy, conventionally heat is converted into mechanical energy in a heat engine. The mechanical energy is subsequently converted into the electrical energy in a generator. As an alternative to this, heat may also be converted into electrical energy directly by using the Seebeck effect. The Seebeck effect occurs when an electrical conductor has a temperature gradient, which means that it has a cold location and a warm location. As a result, an electrical voltage is produced between the two locations on account of the electrons at the cold location and at the warm location having different kinetic energy. The effect that is the reverse of the Seebeck effect is the Peltier effect, which is used in a Peltier element. In the Peltier element, a current flow leads to a temperature gradient in the Peltier element.

Conventional devices that use the Seebeck or Peltier effect have thermo legs of a thermoelectric material approximately 1 mm in height. The thermo legs are applied to alumina plates of good thermal conductivity, as a result of which the devices are rigid and inflexible.

### SUMMARY

One potential object is to provide a thermoelectric generator pipe and a method for producing the generator pipe, it being possible for electrical energy to be generated effectively by the generator pipe with the aid of a heat source.

The inventors propose a thermoelectric generator pipe for generating electrical energy by a heat source and/or a heat sink enclosed by the generator pipe is formed by a helix structure which has an inner conductive strip that is electrically conductive and situated on the inside and an outer conductive strip that is electrically conductive and situated on the outside, which strips are substantially of the same width and are wound with the same pitch such that the windings are electrically insulated from one another and the windings of the inner conductive strip and the windings of the outer conductive strip are staggered and arranged at a radial distance from one another, so as to form between the outer conductive strip and the inner conductive strip two intermediate spaces, which are respectively arranged between the one edge of the inner conductive strip and the directly adjacently arranged edge of the outer conductive strip, so that the intermediate spaces are formed in the manner of a double helix, a first layer, which has p-doped, thermoelectric and percolating particles, being arranged in one of the intermediate spaces and a second layer, which has n-doped, thermoelectric and percolating particles, being arranged in the other intermediate space, the layers being electrically conductive with their respectively adjacently arranged sections of the conductive strips and the generator pipe being slit at least once in the axial direction, so that the generator pipe is subdivided into sections that form thermoelectric elements connected in series.

The inventors also propose a method for producing the thermoelectric generator pipe involves the following: introducing p-doped, thermoelectric and percolating particles into a first flexible synthetic resin; introducing n-doped, thermoelectric and percolating particles into a second flexible synthetic resin; producing a first strip by applying the first synthetic resin to a first carrier matrix; producing a second strip by applying the second synthetic resin to a second carrier matrix; winding an electrically conductive inner conductive strip to form an inner helix structure, the edges of the inner conductive strip being electrically insulated from one another from winding to winding; winding the strips onto the inner conductive strip to form a double helix structure, the strips being arranged in a region that lies between the edges of the inner conductive strip, the edges of the strips being electrically insulated from one another and the strips being electrically conductive with their respectively adjacently arranged sections of the inner conductive strips; winding an electrically conductive outer conductive strip that is of substantially the same width as the inner conductive strip onto the strips to form an outer helix structure, the windings of the inner conductive strip and the windings of the outer conductive strip being staggered, the strips being electrically conductive with their respectively adjacently arranged sections of the outer conductive strips and the edges of the outer conductive strip being electrically insulated from one another from winding to winding; producing at least one axial slit in the generator pipe, so that the generator pipe is slit in the axial direction and is subdivided into sections that form thermoelectric elements connected in series.

The helix structure comprises the inner helix structure, the double helix structure and the outer helix structure. The generator pipe can be advantageously wound up on heat sources of any desired geometries. The heat source may for example be an exhaust pipe, it being possible for the exhaust pipe to have any desired cross section, such as for example a circular, rectangular or oval cross section. With a given length of the generator pipe, the number of thermoelectric elements connected in series can be chosen by fixing the width of the strips and the conductive strips, whereby the electrical voltage that can be picked off from the generator pipe can be advantageously set. Alternatively, it is conceivable not to provide an outer conductive strip and not to slit the helix structure, whereby the generator pipe is formed with a single thermoelectric element.

The fact that the particles are in the layers in a percolating state means that there forms a network of particles that joins the edge points of the layers to one another, so that the layers are electrically conductive. The conductive strips are preferably metallic and may for example comprise copper and/or aluminum.

Preferably, the first layer and/or the second layer are respectively sintered with their particles. During the sintering, the surfaces of the particles melt, so that once the surfaces solidify the particles are bonded to one another. This advantageously produces a high electrical conductivity of the layers. The particles preferably comprise bismuth telluride, in particular bismuth(III) telluride Bi₂Te₃. However, other thermoelectric materials may also be used.

The first layer and/or the second layer preferably have a matrix of a synthetic resin. As a result, the layers have a high mechanical strength. Preferably, the synthetic resin has a high inorganic component, in particular a siloxane, in particular a silicone elastomer. Preferably, the thicknesses of the first layer and of the second layer are chosen such that the electrical resistances of the layers in the radial direction are substantially the same.

The carrier matrixes preferably comprise an electrically nonconductive woven fabric and/or an electrically nonconductive nonwoven fabric; in particular, the carrier matrixes comprise PET (polyethylene terephthalate).

The thermoelectric particles are preferably sintered by supplying heat into the generator pipe. The fact that the particles are only sintered after the winding of the strips means that before the winding they are loose in the strips, so that the strips have the flexibility required for the winding. Preferably, the supply of heat is chosen such that the first synthetic resin and/or the second synthetic resin is/are burned out. Burning out the synthetic resins is appropriate in particular in the case of organic synthetic resins, which only

have a low thermal stability. After burning out, only the thermoelectric particles remain in the layers, so that the layers are advantageously thermally stable. It is also preferred likewise to burn out the carrier matrix.

Preferably, the supply of heat is chosen such that the first synthetic resin and/or the second synthetic resin vitrifies/vitrify. This is the case in particular if an inorganic synthetic resin, in particular siloxane, is used. Synthetic resins with high inorganic components have a high thermal stability, so that, by contrast with the organic synthetic resins, the layers have a high thermal stability even when they remain in the layers. The synthetic resins remaining in the layers allow the layers to be formed with high mechanical strength.

The synthetic resin is preferably a thermoplastic with a glass transition temperature below room temperature, in particular polyethylene glycol, polyvinylpyrrolidone, polyvinyl alcohol and/or a thermoplastic based on acrylonitrile. In this way it is advantageously ensured that the strips are flexible and can be wound. As an alternative to this, the synthetic resin is preferably an uncrosslinked or partially crosslinked thermoset, in particular an uncrosslinked epoxy resin or partially crosslinked epoxy resin, in particular with dicyandiamide as the hardener. The uncrosslinked and partially crosslinked thermosets can preferably be wound. Furthermore, the uncrosslinked thermoset and the partially crosslinked thermoset are adhesive. Preferably, the synthetic resins are applied to the carrier fabric by doctor blading and/or by dip impregnation. The outer conductive strip is preferably wound onto the strips under a mechanical pretension. In this way it is ensured that, if there is any shrinkage of the strips during sintering, the conductive strips are in electrical contact with the strips.

### BRIEF DESCRIPTION OF THE DRAWINGS

These and other objects and advantages of the present invention will become more apparent and more readily appreciated from the following description of the preferred embodiments, taken in conjunction with the accompanying drawings of which:

FIGS. 1, 2, and 3 respectively show a perspective view of a generator pipe at a point in time during the winding,

FIG. 4 shows a longitudinal section through the finished generator pipe and

FIG. 5 shows a thermoelectric element of the generator pipe.

### DETAILED DESCRIPTION OF THE PREFERRED EMBODIMENT

Reference will now be made in detail to the preferred embodiments of the present invention, examples of which are illustrated in the accompanying drawings, wherein like reference numerals refer to like elements throughout.

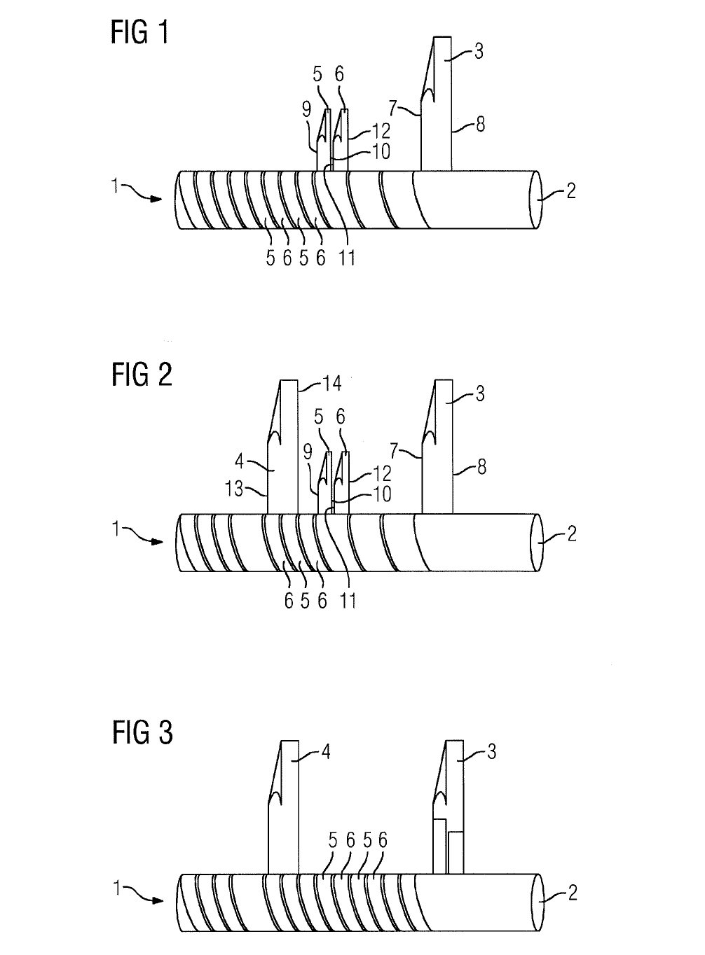

As can be seen from FIGS. 1 to 3, a generator pipe 1 encloses a heat source 2. The heat source 2 has the form of a cylinder, but other forms, such as for example a cuboid, are also conceivable. The generator pipe 1 has an electrically conductive inner conductive strip 3, an electrically conductive outer conductive strip 4, a first strip 5, which has p-doped, thermoelectric and percolating particles, and a second strip 6, which has n-doped, thermoelectric and percolating particles. The inner conductive strip 3, the outer conductive strip 4, the first strip 5 and the second strip 6 respectively have a first edge 7, 13, 9, 11 and respectively have a second edge 8, 14, 10, 12, the edges 7 to 14 respectively being arranged on the longitudinal sides of the conductive strips 3, 4 and the strips 5, 6. The first edges 7, 13, 9, 11 and the second edges 8, 14, 10, 12 are respectively arranged on the same axial side.

The inner conductive strip 3 is wound helically and directly onto the heat source 2, a first gap 26 being provided between the first edge 7 and the second edge 8 of the inner conductive strip and being of such a width that each winding of the inner conductive strip 3 is electrically insulated from the windings of the inner conductive strip 3 arranged adjacent to it. If the surface of the heat source 2 is electrically conductive, it is necessary that an electrically insulating layer is applied to the surface of the heat source 2.

Applied directly to the inner conductive strip 3 are the two strips 5, 6, the first edge 9 of the first strip 5 being flush with the first edge 7 of the inner conductive strip 3 and the second edge 12 of the second strip 6 being flush with the second edge 8 of the inner conductive strip 3. A second gap 27 and a third gap 28 are provided between the edges 9 to 12 of the strips 5, 6 and are of such a width that each winding of the strips 5, 6 is electrically insulated from the windings of the strips 5, 6 arranged adjacent to it. In FIG. 2, first the inner conductive strip 3 is wound onto the heat source 2 and then the strips 5, 6 are wound onto the inner conductive strip 3. In FIG. 3, the strips 5, 6 are first applied to the inner conductive strip 3 and then the inner conductive strip 3 is wound together with the strips 5, 6 onto the heat source 2 in a single method step.

As can be seen from FIGS. 2 and 3, the outer conductive strip 4 is wound directly onto the strips 5, 6 with an offset of half the pitch in relation to the inner conductive strip 3. In this case, the second edge 10 of the first strip 5 is flush with the second edge 14 of the outer conductive strip 4 and the first edge 11 of the second strip 6 is flush with the first edge 13 of the outer conductive strip 4. A fourth gap 29 is provided between the edges 13, 14 of the outer conductive strip 4 and is of such a width that each winding of the outer conductive strip 4 is electrically insulated from the windings of the outer conductive strip 4 arranged adjacent to it. The gaps 26 to 29 may for example be 100 μm wide and an electrically insulating material may have been introduced into the gaps 26 to 29.

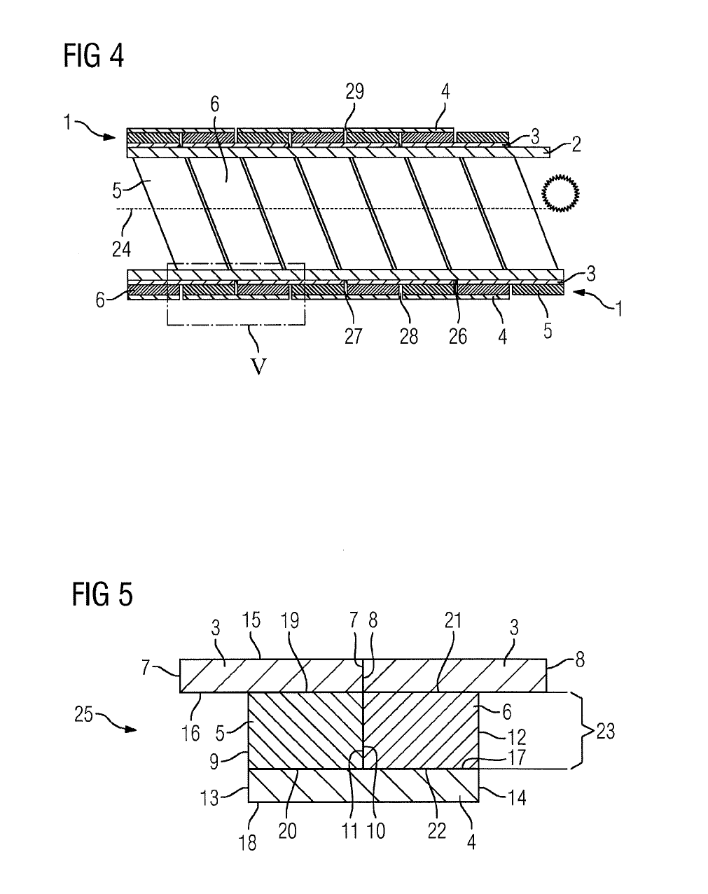

FIG. 4 shows a longitudinal section of the finished generator pipe 1, which encloses the heat source. Arranged directly on the heat source 2 are three layers, the first layer, which has been applied directly to the heat source 2, comprising the inner conductive strip 3. The second layer, which has been applied directly to the first layer, comprises the first strip 5 and the second strip 6 alternately in the axial direction. The third layer, which has been applied directly to the second layer, comprises the outer conductive strip 4. Likewise represented in FIG. 4 is a slit 24, which severs all three layers in the axial direction.

The slit 24 has the effect of forming a plurality of thermoelectric elements connected in series, the cross section of a thermoelectric element 25 being represented in the view of the detail in FIG. 5. The inner conductive strip 3, the outer conductive strip 4, the first strip 5 and the second strip 6 respectively have an inner side 15, 17, 19, 21 and respectively have an outer side 16, 18, 20, 22. The two conductive strips 3, 4 are arranged at a radial distance 23 in relation to one another. During the operation of the generator pipe 1, there is a temperature gradient in the strips 5, 6, the inner sides 19, 21 being warmer than the outer sides 20, 22.

As can be seen from FIG. 5, the strips 5, 6 are arranged with their outer sides 20, 22 directly adjacent to the inner side 17 of a winding of the outer conductive strip 4. The strips 5, 6 are in contact with the outer conductive strip 4 in such a way that the strips are connected with their outer sides 20, 22 to one another in an electrically conductive manner via the outer conductive strip 4. The strips 5, 6 are arranged with their inner sides 19, 21 directly adjacent to the outer side 16 of the inner conductive strip 3, the first strip 5 and the second strip 6 being arranged at two adjacently arranged windings of the inner conductive strip 3. Because the layers have the slit 24 in the axial direction, adjacently arranged windings are electrically insulated from one another. The strips 5, 6 are in contact with the inner conductive strip 3 in such a way that the strips are connected with their inner sides 19, 21 to one another in an electrically conductive manner via the inner conductive strip 3. Since the inner conductive strip 3 is arranged offset from the outer conductive strip, a series connection of thermoelectric elements 25 is obtained.

The method for producing the generator pipe is to be carried out by way of example as follows: introducing p-doped, thermoelectric and percolating particles, which comprise bismuth(III) telluride, into a first flexible synthetic resin, which comprises a thermoplastic; introducing n-doped, thermoelectric and percolating particles, which comprise bismuth(III) telluride, into a second flexible synthetic resin, which comprises a thermoplastic; producing a first strip 5 by applying the first synthetic resin to a first carrier fabric by dip impregnation; producing a second strip 6 by applying the second synthetic resin to a second carrier fabric by dip impregnation; winding an electrically conductive inner conductive strip 3 to form an inner helix structure, the edges 7, 8 of the inner conductive strip 3 being electrically insulated from one another from winding to winding; winding the strips 5, 6 onto the inner conductive strip 3 to form a double helix structure, the edges 9 to 12 of the strips 5, 6 being electrically insulated from one another and the strips 5, 6 being arranged throughout with their inner sides 19, 21 directly on the inner conductive strips 3, whereby the strips 5, 6 are electrically conductive with their respectively adjacently arranged sections of the inner conductive strips 3; winding an electrically conductive outer conductive strip 4 that is of substantially the same width as the inner conductive strip 3 to form an outer helix structure, the windings of the inner conductive strip 3 and the windings of the outer conductive strip 4 being staggered, the strips 5, 6 being electrically conductive with their respectively adjacently arranged sections of the outer conductive strips 4 and the edges of the outer conductive strip 4 being electrically insulated from one another from winding to winding; producing at least one axial slit 24 in the generator pipe 1, so that the generator pipe 1 is slit in the axial direction and is subdivided into sections that form thermoelectric elements 25 connected in series; sintering the thermoelectric particles by supplying heat into the generator pipe 1, the supply of heat being chosen such that the first synthetic resin and the second synthetic resin are burned out.

The invention has been described in detail with particular reference to preferred embodiments thereof and examples, but it will be understood that variations and modifications can be effected within the spirit and scope of the invention covered by the claims which may include the phrase “at least one of A, B and C” as an alternative expression that means one or more of A, B and C may be used, contrary to the holding in Superguide v. DIRECTV, 69 USPQ2d 1865 (Fed. Cir. 2004).

1-15. (canceled)

16. A thermoelectric generator pipe for generating electrical energy from a heat source and/or a heat sink enclosed by the generator pipe, the thermoelectric generator pipe comprising:
an inner conductive strip that is electrically conductive and wound helically onto the heat source and/or heat sink such that adjacent windings of the inner conductive strip are electrically insulated from one another;
a first strip, which has p-doped, thermoelectric and percolating particles, applied to the inner conductive strip;
a second strip, which has n-doped, thermoelectric and percolating particles, applied to the inner conductive strip; and
an outer conductive strip that is electrically conductive and wound helically onto the first and second strips such that adjacent windings of the outer conductive strip are electrically insulated from one another, the outer conductive strip having a width substantially the same as a width of the inner conductive strip and being wound with a same pitch as the inner conductive strip, the windings of the outer conductive strip being arranged at a radial distance from the windings of the inner conductive strip, wherein
the first and second strips are provided within the radial distance,
the outer conductive strip is offset with respect to the inner conductive strip such that:
the windings of the inner and outer conductive strips are staggered;
each winding section of the inner conductive strip is axially positioned at an intersection between two adjacently arranged winding sections of the outer conductive strip;
each winding section of the inner conductive strip has first and second opposite edges;
a first axial space is created between the first edge and the intersection between the two adjacently arranged winding sections of the outer conductive strip;
a second axial space is created between the second edge and the intersection between the two adjacently arranged winding sections of the outer conductive strip;
the first strip is provided in the first axial space; and
the second strip is provided in the second axial space,
the first and second strips are electrically conductive with respectively adjacently arranged sections of the inner and outer conductive strips, and
and the generator pipe is slit at least once in the axial direction, so that the generator pipe is subdivided into sections that form thermoelectric elements connected in series.

17. The thermoelectric generator pipe as claimed in claim 16, wherein the first strip is sintered with the p-doped, thermoelectric and percolating particles and/or the second strip is sintered with the n-doped, thermoelectric and percolating particles.

18. The thermoelectric generator pipe as claimed in claim 16, wherein the p-doped, thermoelectric and percolating particles and/or the n-doped, thermoelectric and percolating particles include bismuth telluride.

19. The thermoelectric generator pipe as claimed in claim 16, wherein the first strip and/or the second strip has a matrix of a synthetic resin.

20. The thermoelectric generator pipe as claimed in claim 19, wherein the synthetic resin has a high inorganic component.

21. The thermoelectric generator pipe as claimed in claim 16, wherein the first strip and the second strip have thicknesses that result in electrical resistances of the first strip and the second strip in the radial direction being substantially the same.

22. A method for producing a thermoelectric generator pipe, comprising:
introducing p-doped, thermoelectric and percolating particles into a first flexible synthetic resin;
introducing n-doped, thermoelectric and percolating particles into a second flexible synthetic resin;
producing a first strip by applying the first synthetic resin to a first carrier matrix;
producing a second strip by applying the second synthetic resin to a second carrier matrix;
winding an electrically conductive inner conductive strip to form an inner helix structure, adjacent windings of the inner conductive strip being electrically insulated from one another;
winding the first and second strips directly onto the inner conductive strip to form a double helix structure, with each winding section of the first strip being axially between two adjacent winding sections of the second strip, the first and second strips being wound such that adjacent windings of the first and second strips are electrically insulated from one another, the first and second strips being electrically conductive with respectively adjacently arranged sections of the inner conductive strip;
winding an electrically conductive outer conductive strip that is of substantially the same width as the inner conductive strip to form an outer helix structure, the windings of the inner conductive strip being staggered with respect to windings of the outer conductive strip, the first and second strips being electrically conductive with respectively adjacently arranged sections of the outer conductive strip, and adjacent windings of the outer conductive strip being electrically insulated from one another; and
producing at least one axial slit in the generator pipe, so that the generator pipe is slit in the axial direction and is subdivided into sections that form thermoelectric elements connected in series.

23. The method as claimed in claim 22, wherein the first and second carrier matrixes include an electrically nonconductive woven fabric and/or an electrically nonconductive nonwoven fabric.

24. The method as claimed in claim 22, further comprising:
sintering the p-doped, thermoelectric and percolating particles and/or the n-doped, thermoelectric and percolating particles by supplying heat into the generator pipe.

25. The method as claimed in claim 24, further comprising choosing the supply of heat such that the first synthetic resin and/or the second synthetic resin is/are burned out.

26. The method as claimed in claim 24, further comprising choosing the supply of heat such that the first synthetic resin and/or the second synthetic resin vitrifies/vitrify.

27. The method as claimed in claim 22, wherein the first and second synthetic resins are thermoplastics with a glass transition temperature below room temperature.

28. The method as claimed in claim 22, wherein the first and second synthetic resins are uncrosslinked or partially crosslinked thermosets.

29. The method as claimed in claim 22, wherein the first and second synthetic resins are applied to the first and second carrier matrixes by doctor blading and/or by dip impregnation.

30. The method as claimed in claim 22, wherein the outer conductive strip is wound onto the first and second strips under a mechanical pretension.

31. The thermoelectric generator pipe as claimed in claim 16, wherein a first edge of the first strip is flush with a first edge of the inner conductive strip, a first edge of the second strip is separated from a second edge of the first strip, a second edge of the second strip is flush with a second edge of the inner conductive strip, the first edge of the second strip is flush with a first edge of the outer conductive strip, and the second edge of the first strip is flush with a second edge of the outer conductive strip.

32. The thermoelectric generator pipe as claimed in claim 18, wherein the p-doped, thermoelectric and percolating particles and/or the n-doped, thermoelectric and percolating particles include bismuth(III) telluride Bi₂Te₃.

33. The thermoelectric generator pipe as claimed in claim 20, wherein the inorganic component is a silicone elastomer.

34. The method as claimed in claim 23, wherein the first and second carrier matrixes include polyethylene terephthalate (PET).

35. The method as claimed in claim 27, wherein the first and second synthetic resins are polyethylene glycol, polyvinylpyrrolidone, polyvinyl alcohol, and/or a thermoplastic based on acrylonitrile.

36. The method as claimed in claim 28, wherein the first and second synthetic resins are an uncrosslinked epoxy resin or partially crosslinked epoxy resin.

37. The method as claimed in claim 36, wherein dicyandiamide is used as a hardener.
